(19) United States
(12) Patent Application Publication
(10) Pub. No.: US 2017/0327372 A1
(43) Pub. Date: Nov. 16, 2017

(54) METHOD FOR MANUFACTURING NANOSTRUCTURES

(71) Applicant: Lightlab Sweden AB, UPPSALA (SE)

(72) Inventors: Jonas TIRÉN, UPPSALA (SE); Yuan-Yao LI, Chia-Yi (TW); Chia-Yen HSU, Chia-Yi (TW); Ying-Pin WU, Taipei City (TW)

(73) Assignee: Lightlab Sweden AB, UPPSALA (SE)

(21) Appl. No.: 15/529,400

(22) PCT Filed: Nov. 19, 2015
(86) PCT No.: PCT/SE2015/051248

§ 371 Date: May 24, 2017

(30) Foreign Application Priority Data
Nov. 26, 2014 (EP) 14194860.4
Nov. 26, 2014 (EP) 14194903.2
Jun. 3, 2015 (EP) 15170518.3

(51) Int. Cl. B82Y 40/00; H01J 1/304; H01J 63/04; H01J 9/02; H01L 29/06

(52) U.S. Cl. CPC B82Y 40/00; H01L 29/0676; H01L 29/0673; H01J 63/04; H01J 9/025; H01J 1/304; C01P 2004/61; C01P 2004/16; C01P 2004/03

(57) ABSTRACT

There is provided a method for manufacturing a plurality of nanostructures comprising the steps of providing a plurality of spherical Zn structures and oxidizing the spherical structures in ambient atmosphere at a temperature in the range of 350° C. to 600° C. for a time period in the range of h to 172 h, such that ZnO nanowires protruding from the spherical structures are formed. There is also provided a field emission arrangement comprising a cathode having the aforementioned ZnO nanowire structures arranged thereon.

### FIELD OF THE INVENTION

The present invention relates to a method for fabricating ZnO nanowires, and in particular to a method for fabricating ZnO nanowires grown from a Zn structure. The present invention also relates to the use of such ZnO structures in a field emission arrangement.

### TECHNICAL BACKGROUND

Traditional incandescent light bulbs are currently being replaced by other light sources having higher energy efficiency and less environmental impact. Alternative light sources include light emitting diode (LED) devices and fluorescent light sources. However, LED devices are expensive and complicated to fabricate and fluorescent light sources are known to contain small amounts of mercury, thereby posing potential health problems due to the health risks involved in mercury exposure. Furthermore, as a result of the mercury content, recycling of fluorescent light sources is both complicated and costly.

An attractive alternative light source has emerged in the form of field emission light sources. A field emission light source includes an anode structure and a cathode structure, the anode structure consists of a transparent electrically conductive layer and a layer of phosphor coated on the inner surface of e.g. a transparent glass tube. The phosphor layer emits light when excited by the electrons emitted from the cathode structure.

Furthermore, it is known that nanostructures are suitable for use as the field emitters in a cathode structure. Several methods for fabricating nanostructures are known. However, it is desirable to provide nanostructures exhibiting improved emission properties.

Accordingly there is a need for an improved method for fabrication of nanostructures for use as field emitters.

### SUMMARY OF THE INVENTION

In view of the above-mentioned and other drawbacks of the prior art, a general object of the present invention is to provide an improved method for fabricating nanostructures suitable for use as field emitters.

According to a first aspect of the present invention, it is provided a method for manufacturing a plurality of nanostructures comprising the steps of providing a plurality of Zn structures and oxidizing the spherical Zn structures in ambient atmosphere at a temperature in the range of 350° C. to 600° C. for a time period in the range of 1 h to 172 h, to form ZnO nanowires protruding from said structures. The advantages of using such particles are for example that they are commonly available at low cost, and they are furthermore easily deposited for example by using, spraying, dipping, spin coating using a colloidal slurry, electrodeposition, screen printing etc. The plurality of Zn structures are preferably essentially spherical.

The present invention is further based on the realization that ZnO nanowires may be easily produced using only the ambient air at ambient pressure as a reaction gas when oxidizing a substantially spherical Zn structure. The ambient atmosphere may be controlled further by using different mixtures of O₂ and N₂. Thereby, a simple and cost effective manufacturing process is provided. It further relies on the realization that the electrical field needed for field emission is amplified in two steps: The first step is achieved by the Zn-particles themselves, typically giving a local amplification of the electrical field of 2-20 times, thus giving lower requirements on the field amplification by the nanostructures. Thus, the Zn particles (typically in the size of 1 um-100 um) acts as a source of Zn for the subsequently formed nanowires, and at the same time acts like field enhancing elements, otherwise costly to design and manufacture. The field emission properties of similar structures comprising features in the micrometer and in the nanometer range are further discussed in published patent applications WO2013050570 and EP2375435A1, hereby incorporated by reference.

The substrate may typically be a conventional silicon substrate. However, other substrate materials including metallic materials may equally well be used. In the present context, the term nanowire refers to a structure where at least one dimension is on the order of up to a few hundreds of nanometers. Such nanowire may also be referred to as nanotubes, nanorods, nanopencils, nanospikes, nanoneedles, and nanofibres.

Employing the growth method described above is advantageous in that the process is easy and may be performed without complicated and expensive process equipment that is frequently required for high-temperature growth methods, such as thermal decomposition, thermal evaporation, physical vapor deposition (PVD) or chemical vapor deposition (CVD). In particular, the nanostructure can be manufactured using only low cost raw materials and a conventional furnace.

Moreover, through the above described process, a tapered nanowire having a high aspect ratio is provided. A high aspect ratio of the nanowire is desirable as it results in higher electric field strength at the tip of the nanorod, thereby leading to improved field emission performance. Aspect ratio should in the present context be understood as the length to width ratio of the nanostructure where the length is defined in a direction away from the spherical structure.

The population density of nanowires on the sphere, and the aspect ration of nanowires, can be controlled by tuning the reaction temperature and the oxidation time. A low density of long nanowires may provide advantageous field emission properties since screening effects can be reduced or avoided.

In one embodiment of the invention, the spherical Zn structures may be provided on the surface of a substrate to facilitate manufacturing. The spherical structures may for example be provided in the form of a Zn powder being sprayed on the substrate.

Moreover, the diameter of the spherical Zn structures may be in the range of 1-100 μm and the ZnO nanowires may advantageously be grown to a length in the range of 3-7 μm and having a tip radius in the range of 10-30 nm.

According to one embodiment of the invention, the oxidizing step may advantageously be performed at a temperature in the range of 350° C. to 550° C. for a time period of 36 h to 72 h, for example at 550° C. for 30 h which has proven to provide nanowires having a high aspect ratio and a suitable population density for use in field emission applications.

According to a second aspect of the invention, there is provided a structure comprising a spherical Zn structure having a diameter in the range of 1-100 μm and a plurality of ZnO nanowires extending from the spherical structure, said nanowires having a length in the range of 3-50 μm, and a tip radius in the range of 1 -30 nm. Furthermore, the spherical Zn structure may have a hollow core. The nanowires may advantageously be tapered so that they are narrower towards the tip, which is advantageous with respect to the field emission properties of the nanowire.

According to one embodiment of the invention, the hollow core Zn structure may ZnO shell. The thickness of the ZnO shell in relation to the overall size of the Zn particle is related to the oxidation temperature and time. Further effects and advantages of the second aspect of the invention are largely analogous to those discussed above in relation to the manufacturing method.

The above discussed Zn structure comprising ZnO nanowires may advantageously be provided on a substrate to be used as a cathode for a field emission lighting arrangement.

Furthermore, the Zn structure comprising ZnO nanowires may advantageously be provided on a wire to be used as a cathode for a field emission lighting arrangement. The wire is typically a conductive wire comprising a metal, where the wire is substantially larger than the nanowires. It should however be understood that the Zn structure comprising nanowires can be formed on practically any substrate capable of withstanding the oxidation temperatures.

There is also provided a field emission arrangement comprising: an anode structure at least partly covered by a phosphor layer, said anode structure being configured to receive electrons emitted by a field emission cathode as discussed above, an evacuated chamber in which said anode structure and field emission cathode is arranged, and a power supply connected to the anode and the field emission cathode configured to apply a voltage so that an electron is emitted from the cathode to the anode.

### BRIEF DESCRIPTION OF THE DRAWINGS

These and other aspects of the present invention will now be described in more detail with reference to the appended drawings showing an example embodiment of the invention, wherein:

FIG. 1 is a flow chart outlining the general process steps of a method for manufacturing a nanostructure according to an embodiment of the invention;

FIGS. 2a-c schematically illustrates the manufacturing process according to an embodiments of the invention;

FIG. 3a-c illustrates nanostructures according to various embodiments of the invention; FIG. 4a-h illustrates nanostructures according to various embodiments of the invention;

FIG. 5 schematically illustrates a cathode structure according to an embodiment of the invention; and

FIG. 6 schematically illustrates a field emission arrangement according to an embodiment of the invention.

### DETAILED DESCRIPTION OF PREFERRED EMBODIMENTS OF THE INVENTION

In the present detailed description, various embodiments of a method for fabricating nanostructures according to the present invention are mainly discussed with reference to ZnO nanostructures suitable for use as field emitters. It should be noted that this by no means limits the scope of the present invention which is equally applicable to nanostructures comprising other materials. Like reference characters refer to like elements throughout.

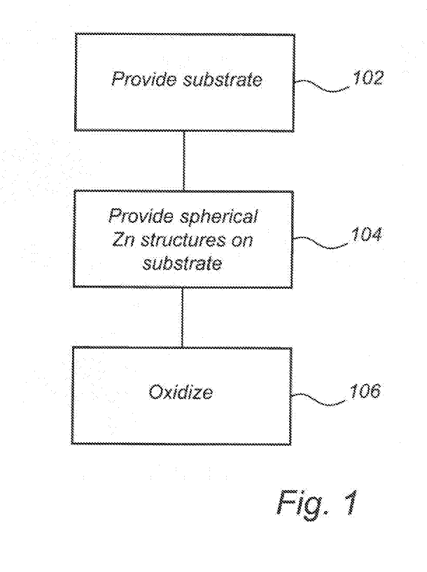

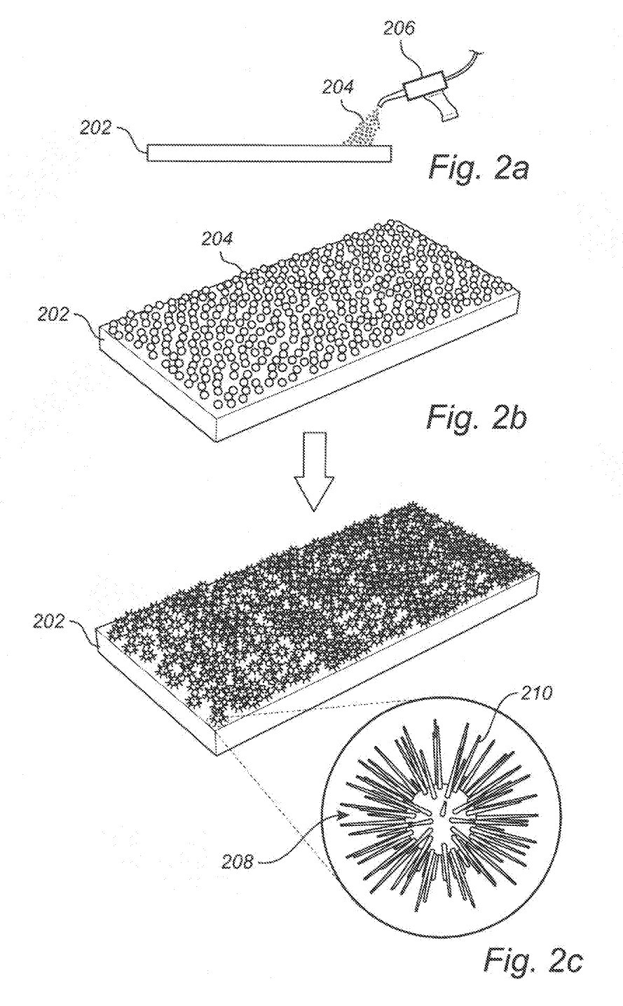

A method according to various embodiments of the present invention will now be described with reference to the flow-chart shown in FIG. 1 outlining the general method steps for fabrication of nanostructures and to FIGS. 2a-c schematically outlining the fabrication process.

In a first step 102, a substrate 202 is provided. The substrate 202 may for example be a conventional semiconductor substrate such as a silicon substrate. However, the substrate 202 may equally well be made from materials such as SiO₂, quartz, Al₂O₃, metallic substrates such as (but not limited to) stainless steel etc.

Next, spherical Zn particles 204 are provided on the substrate. The particles typically have a diameter from a few micrometers up to several tens of micrometers, with an average particle size of approximately 6-9 micrometers. Moreover, the particles may for example be provided to the surface of the substrate by means of pressurized air blowing a Zn powder onto the surface. The Zn powder may for example be any commercially available Zn powder having a purity of preferably at least 97%. As illustrated in FIG. 2a, an air gun 206 may be used to deposit the Zn particles. Once the plurality of particles is deposited on the surface of the substrate 202 in a desired concentration, the substrate 202 with the layer of Zn particles is inserted into an oxidation furnace for thermal oxidation.

In step 106, the Zn particles are oxidized in ambient air at a temperature of 450° C. for a time period of about 72 h such that ZnO nanowires 210 are grown radially from the Zn core particles as shown in FIG. 2c. The population density and aspect ratio of the ZnO nanowires can be controlled by controlling the oxidation temperature and oxidation time, and other times and temperatures within the claimed ranges are thus feasible. In particular, similar results have been found for an oxidation time of 36 h at a temperature of 550° C. Accordingly, an increase in temperature also increases the oxidation rate. An increased oxidation rate may be preferable for ZnO nanowire growth in the [100] direction, as observed through TEM and XRD analysis. Observed population densities have increased from below 10 nanowires/μm2 at an oxidation temperature of 350° C. to approximately 13 nanowires/μm2 at an oxidation temperature of 550° C., an increase in population density of more than 30%. The oxidation of the Zn core particle also leas to a volume expansion of the core particle as oxidation cases oxygen to interdiffused with the Zn core.

FIG. 2c schematically illustrates an oxidized Zn particle 208 having nanowires 210 extending substantially perpendicularly from the particle.

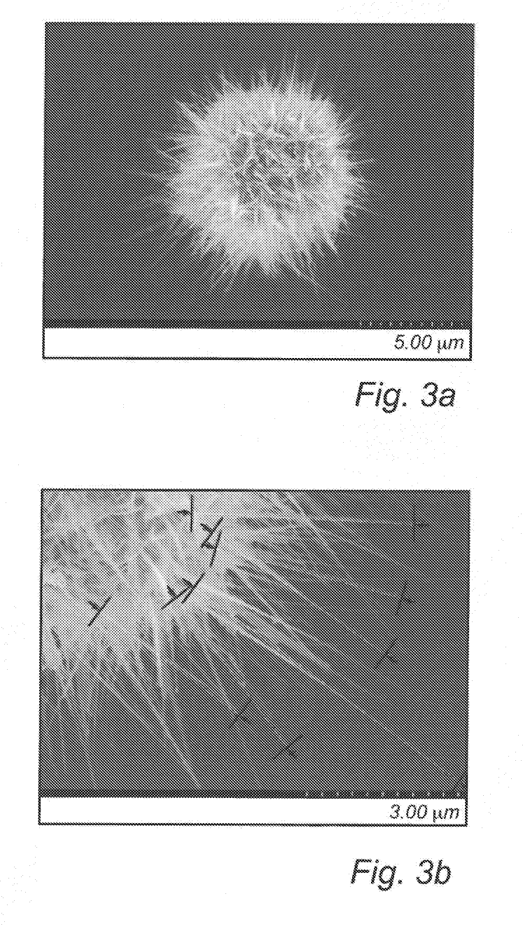

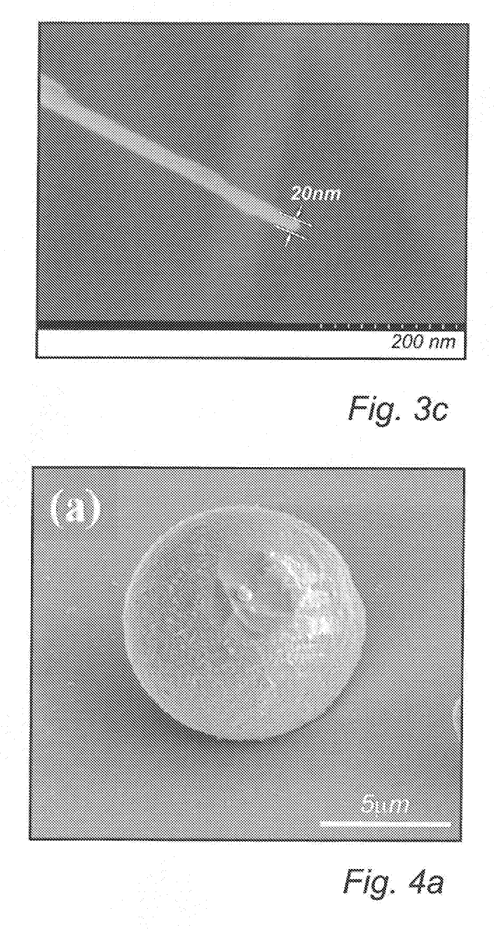

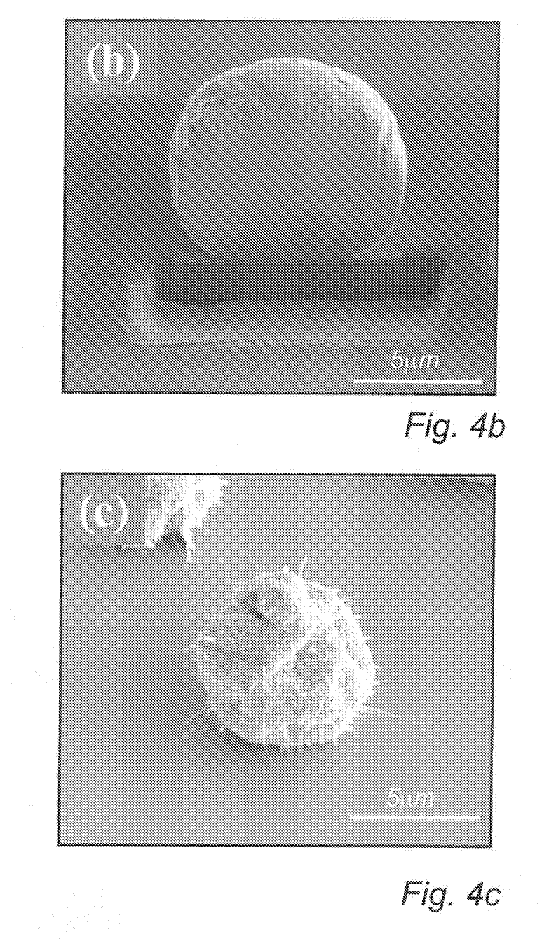

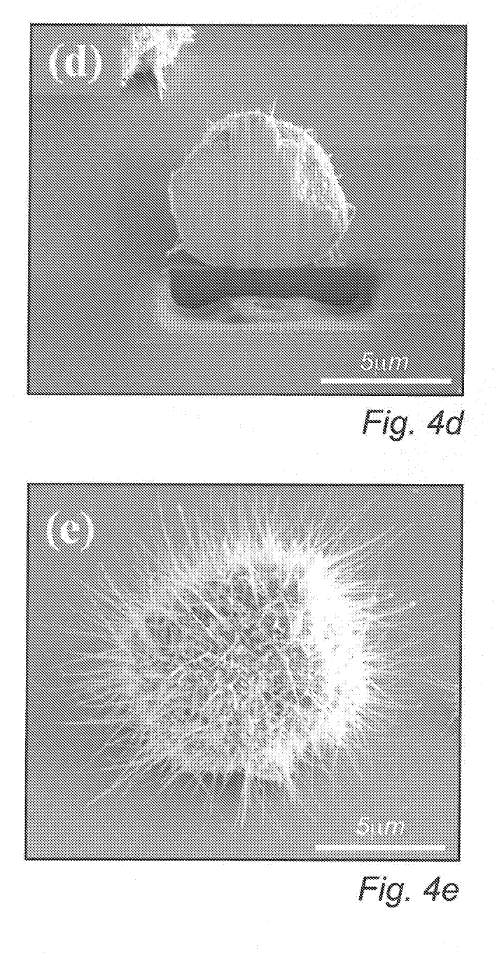

FIG. 3a illustrates a Zn particle having ZnO nanowires grown thereon. The nanowire length is typically on the same order as the diameter of the Zn particle. In particular, the length of the illustrated nanowires is in the range of 3-7 micrometers as can be seen in FIG. 3b.

FIG. 3c illustrates an individual ZnO nanowire grown from a Zn particle. Here it can be seen that the nanowire tip has a radius of about 20 nanometers. The sharp tip of the nanowire makes it particularly useful in field emission applications as electron emission properties depends on the aspect ratio of the nanowire and on the sharpness of the tip of the electron emitter, i.e. the ZnO nanowire. It has also been observed that the tip diameter can be controlled by controlling the oxidation temperature, where a higher oxidation temperature provides nanowires with tips having a smaller radius, where tips of nanowires grown at 550° C. exhibit an average tip radius of about 18 nm. At the same time, the aspect ratio (length/diameter) of the nanowires is increased with an increasing oxidation temperature.

FIGS. 4a-h illustrate the Zn structure at different stages of the manufacturing process, where FIGS. 4b, d, f and h illustrate cross sections of the core particle where the particle has been sectioned by focused ion beam milling. FIG. 4a illustrates a Zn particle prior to oxidation, having a diameter of approximately 5 μm, to be used as a starting material. As can be seen in FIG. 4b, the Zn core particle is entirely solid.

FIG. 4c illustrates the Zn particle after thermal oxidation at 450° C. for 6 h, and the cross section of FIG. 4d shows that the particle is still solid.

FIG. 4e illustrates that, when increasing the oxidation time to 24 hours, the length and population density of the ZnO nanowires were increased on the core particle. Furthermore, a hollow core was created as shown in FIG. 4f. FIGS. 4g and 4h show the surface and inner structure of the urchin-like microsphere, respectively, after an oxidation time of 72 hours.

EDS analysis of the resulting particle illustrated in FIG. 4g show that no oxygen was found near the edge of the hollow core while zinc was present in the whole sphere. It can therefore be concluded that a zinc layer exists around the hollow core as an inner shell and a zinc oxide layer is an outer shell, as a result of the oxidation of the surface of the structure.

The current density from a field emitting device comprising the above described nanostructures has been formed, and tests have shown that nanostructures oxidized at a higher temperature results in a higher current density as a function of applied field. Moreover, the current density is shown to exhibit a Fowler-Nordheim behavior indicating that Fowler-Nordheim tunneling is the primary mechanism responsible for electron emission.

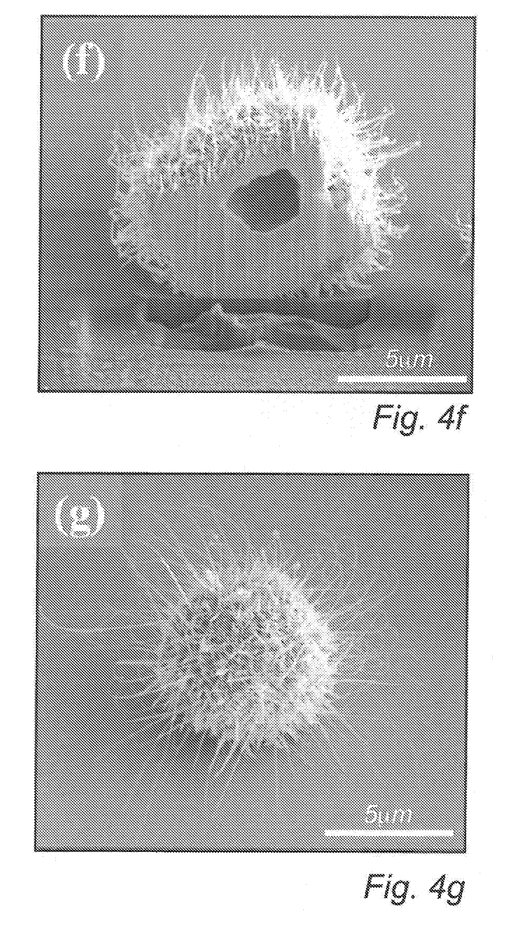

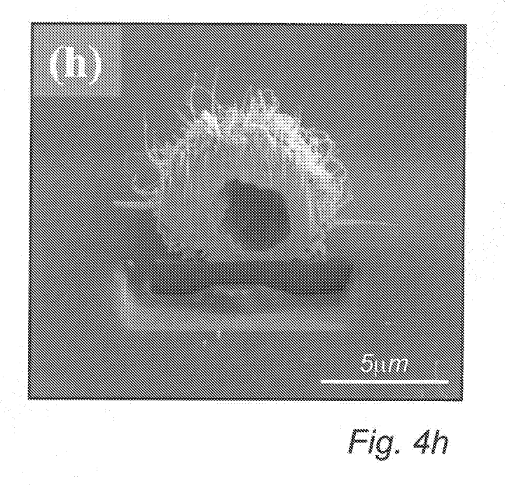

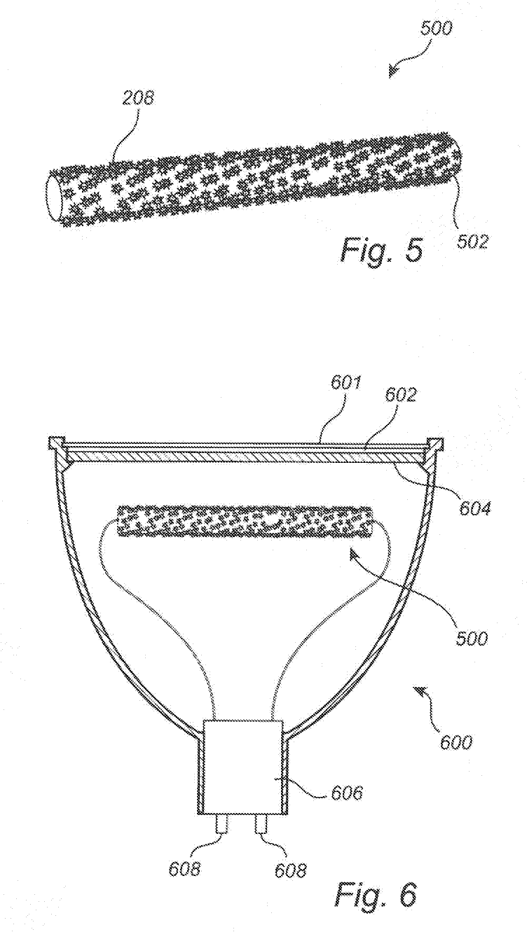

FIG. 5 schematically illustrates a cathode structure 500 comprising a wire 502 comprising a plurality of structures 208 according to any one of the aforementioned embodiments.

FIG. 6 further illustrate a field emission arrangement 600 comprising an anode structure 602 at least partly covered by a phosphor layer 604. The anode structure is configured to receive electrons emitted by the field emission cathode 500. The field emission arrangement 600 further comprises an evacuated chamber 601 in which the anode structure 602 and field emission cathode 500 is arranged. A power supply 606 is connected to the anode 602 and to the field emission cathode 500, configured to apply a voltage so that an electron is emitted from the cathode 500 to the anode 602, thereby exciting the phosphor layer such that photons are emitted. The power supply further comprises connectors 608 for connecting the field emission arrangement 600 to an external power source.

Moreover, the manufacturing process described herein may be complemented by additional steps aiming to form a cathode structure for a field emission arrangement. For example, a pattern of Zn particles comprising ZnO nanowires may be formed. The pattern may be formed either before or after oxidation of the Zn particles, and conventional methods such as photolithography may be used to form a desired pattern of ZnO nanowire structures.

Additionally, a metal pattern may be formed on the substrate prior to deposition of the ZnO particles to form a conductive grid or array, or to form individually addressable sites where ZnO structures are formed.

The Zn particles may also be deposited and subsequently oxidized on other structures than a planar substrate. Other structures suitable for use as a cathode in a field emission arrangement may for example comprise conductive wires and the like. In particular, the described manufacturing method allows for formation of ZnO nanowires on structures haven any shape or form, since the deposition of Zn particles and oxidation is not limited by process steps requiring a planar surface to perform.

The person skilled in the art realizes that the present invention by no means is limited to the preferred embodiments described above. On the contrary, many modifications and variations are possible within the scope of the appended claims.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

1. A method for manufacturing a plurality of nanostructures comprising the steps of:
providing a plurality of Zn structures; and
oxidizing said structures in ambient atmosphere at a temperature in the range of 350° C. to 550° C. for a time period in the range of 36 h to 72 h, such that ZnO nanowires protruding from said structures are formed.

2. The method according to claim 1, wherein said plurality of Zn structures are essentially spherical.

3. The method according to claim 1, wherein said Zn structures are provided on the surface of a substrate.

4. The method according to claim 1, wherein a diameter of said Zn structures is in the range of 1-100 μm.

5. The method according to claim 1, wherein said ZnO nanowires are grown to a length in the range of 3-7 μm.

6. The method according to claim 1, wherein said ZnO nanowires are grown to have a tip radius in the range of 10-30 nm.

7. The method according to claim 1, wherein said Zn structures are provided in the form of a Zn powder being sprayed on said substrate.

8. (canceled)

9. A structure comprising;
a Zn structure having a diameter in the range of 1-100 μm;
a plurality of ZnO nanowires extending from said Zn structure, said nanowires having a length in the range of 3-7 μm, and a tip radius in the range of 10-30 nm, wherein said structures are formed by oxidation in ambient atmosphere at a temperature in the range of 350° C. to 550° C. for a time period in the range of 36 h to 72 h.

10. The structure according to claim 9, wherein said plurality of Zn structures are essentially spherical.

11. The structure according to claim 9, wherein said Zn structure has a hollow core.

12. The structure according to claim 9, wherein said Zn structure comprises a ZnO shell.

13. The structure according to claim 9, wherein said ZnO nanowire is tapered.

14. The structure according to claim 9, wherein said nanowires have a uniform length distribution.

15. A cathode configured to be used in a field emission lighting arrangement, said cathode comprising:
a substrate comprising a plurality of structures according to claim 9.

16. A cathode configured to be used in a field emission lighting arrangement, said cathode comprising:
a wire comprising a plurality of structures according to claim 9.

17. A field emission arrangement comprising:
an anode structure at least partly covered by a phosphor layer, said anode structure being configured to receive electrons emitted by a field emission cathode according to claim 15;
an evacuated chamber in which said anode structure and field emission cathode is arranged; and
a power supply connected to the anode and the field emission cathode configured to apply a voltage so that an electron is emitted from the cathode to the anode.

17. A field emission arrangement comprising:
an anode structure at least partly covered by a phosphor layer, said anode structure being configured to receive electrons emitted by a field emission cathode according to claim 16;
an evacuated chamber in which said anode structure and field emission cathode is arranged; and
a power supply connected to the anode and the field emission cathode configured to apply a voltage so that an electron is emitted from the cathode to the anode.
